(19) United States
(12) Patent Application Publication
(10) Pub. No.: US 2007/0218639 A1
(43) Pub. Date: Sep. 20, 2007

(54) Formation of a smooth polysilicon layer

(76) Inventor: Fransiska Dwikusuma, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/377,706

(22) Filed: Mar. 15, 2006

(51) Int. Cl. H01L 21/336

(52) U.S. Cl. 438/287; 438/591

(57) ABSTRACT

Embodiments of the invention provide a polysilicon layer on a high-k dielectric layer with a smooth upper surface. The polysilicon layer may be formed by pretreating a wafer with a substrate, the high-k dielectric layer on the substrate and a capping layer on the high-k dielectric layer at a first temperature in a chemical vapor deposition chamber. The polysilicon layer may then be formed on the capping layer in the chemical vapor deposition chamber at a second temperature higher than the first temperature.

### BACKGROUND

### Background of the Invention

Transistors, such as NMOS and PMOS transistors, may be formed with a gate electrode that includes a metal gate electrode material. These transistors may be fabricated using a “replacement gate” process, in which a sacrificial gate electrode layer comprising polysilicon is formed. This polysilicon gate electrode layer may be removed and at least partially replaced by the metal gate electrode material.

### BRIEF DESCRIPTION OF THE DRAWINGS

FIG. 1 is a cross sectional side view that illustrates a semiconductor substrate with a smooth polysilicon according to one embodiment of the present invention.

FIG. 2 is a flow chart that shows how the smooth polysilicon layer shown in FIG. 1 may be formed, according to one embodiment of the present invention.

FIG. 3 is a cross sectional side view that illustrates the substrate.

FIG. 4 is a cross sectional side view that illustrates the high-k layer formed on the substrate.

FIG. 5 is a cross sectional side view that illustrates the capping layer formed on the high-k layer.

FIG. 6 is a cross sectional side view that illustrates the pretreatment of the wafer.

FIG. 7 is a cross sectional side view that illustrates the formation of the polysilicon layer.

FIG. 8 is a cross sectional side view that illustrates the wafer after portions of the high-k layer, capping layer, and polysilicon layer have been removed.

FIG. 9 is a cross-sectional side view that illustrates spacers formed adjacent the sidewalls of the patterned high-k, capping, and polysilicon layers.

FIG. 10 is a cross-sectional side view that illustrates a first interlayer dielectric layer (ILD layer) and a trench.

FIG. 11 is a cross-sectional side view that illustrates a metal gate electrode formed in the trench.

FIG. 12 illustrates a system in accordance with one embodiment of the present invention.

### DETAILED DESCRIPTION

In various embodiments, an apparatus and method relating to the formation of a smooth polysilicon layer are described. In the following description, various embodiments will be described. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

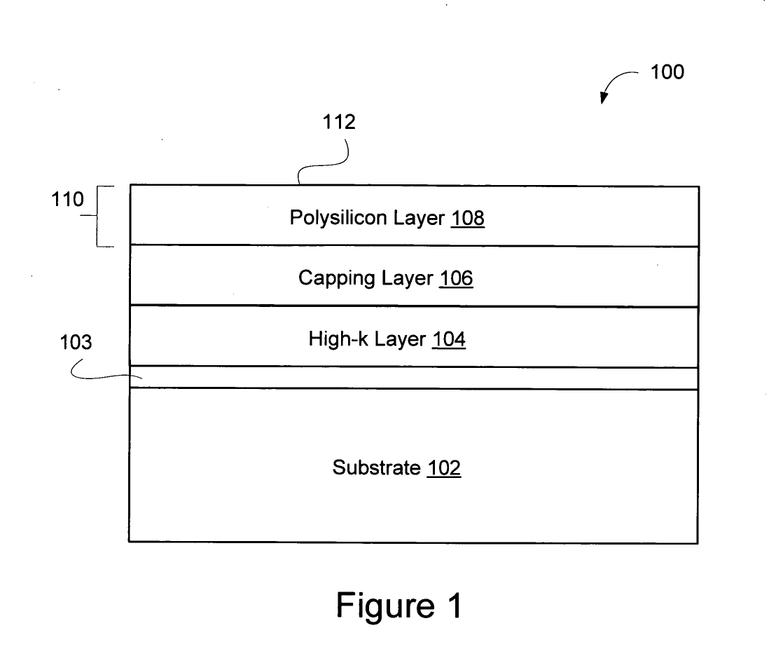

FIG. 1 is a cross sectional side view that illustrates a semiconductor wafer 100 with a smooth polysilicon layer 108 according to one embodiment of the present invention. While FIG. 1 illustrates a wafer 100 with a smooth polysilicon layer 108, in other embodiments a singulated die or another piece of material may have a similar smooth polysilicon layer 108, similarly formed.

The wafer 100 may include a substrate layer 102 in an embodiment. Substrate 102 may comprise any material that may serve as a foundation upon which a semiconductor device may be built. The substrate 102 may be a silicon containing substrate 102. In an embodiment, the substrate 102 may comprise a semiconductor material such as single crystal silicon, silicon germanium, gallium arsenide or another suitable material. In some embodiments, the substrate 102 may be a bulk semiconductor substrate 102, while in other embodiments, the substrate 102 may be a semiconductor-on-insulator (“SOI”) substrate. The substrate 102 may include multiple different layers and/or structures in some embodiments, while in other embodiments the substrate 102 may just be one layer of material.

A high-k dielectric layer 104 (where “high-k” means high dielectric constant value) may be on the substrate layer 102 in some embodiments. The high-k dielectric layer 104 may comprise, for example, hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate. Although a few examples of materials that may be used to form a high-k gate dielectric layer 104 are described here, the high-k dielectric layer 104 may be made from other materials in other embodiments. In some embodiments, a portion of the high-k dielectric layer 104 may later become a gate dielectric layer for a structure such as a transistor. In those embodiments, the high-k dielectric layer 104 may comprise any material suitable for use in the structure.

In some embodiments the high-k dielectric layer 104 may have a k-value higher than about 7.5. In other embodiments, the high-k dielectric layer 104 may have a k-value higher than about 10. In other embodiments, the high-k dielectric layer 104 may comprise a material with a k-value of about 12, or may comprise a material with a higher k-value than that. In other embodiments, the high-k dielectric layer 104 may have a k-value between about 15 and about 25, e.g. HfO₂. In yet other embodiments, the high-k dielectric layer 104 may have a k-value even higher.

In some embodiments, there may be a thin transition layer 103 between the substrate 102 and the high-k dielectric layer 104. The thin transition layer 103 may comprise an oxide material such as silicon dioxide or another material. The thin transition layer 103 may have a thickness of about ten angstroms or less in an embodiment. In another embodiment, the thin transition layer 103 may have a thickness of about five angstroms or less. In yet another embodiment, thin transition layer 103 may have a thickness of about three angstroms or less.

There may be a capping layer 106 on the high-k dielectric layer 104 in some embodiments. A material from which the high-k dielectric layer 104 is comprised may be capable of undesirably interacting with polysilicon of the polysilicon layer 108 in some embodiments. The capping layer 106 may prevent the high-k dielectric layer 104 from contacting the polysilicon layer 108, and thus prevent this undesired interaction. The capping layer 106 may comprise any suitable material, and may comprise a tantalum nitride material, a titanium nitride material, or another material in various embodiments. The capping layer 106 may have a thickness of less than twenty-five angstroms in some embodiments, although in other embodiments it may have different thicknesses.

The smooth polysilicon layer 108 may be on the capping layer 106. The polysilicon layer 108 may have any desired thickness 110. In an embodiment, the thickness 110 may be between about 700 angstroms and about 900 angstroms. In another embodiment, the thickness may be about 800 angstroms. The thickness 110 may be different in other embodiments. While called a polysilicon layer 108, the layer 108 may comprise polysilicon as well as other elements, impurities, or materials.

The polysilicon layer 108 may have a top surface 112 that is smoother than that of polysilicon layers formed by prior processes. In an embodiment, the polysilicon layer 108 may have an RMS roughness of less than 8 nanometers. In another embodiment, the polysilicon layer 108 may have an RMS roughness of less than 6 nanometers. In another embodiment, the polysilicon layer 108 may have an RMS roughness of less than 3 nanometers. In yet another embodiment, the polysilicon layer 108 may have an RMS roughness of about 2 nanometers or less.

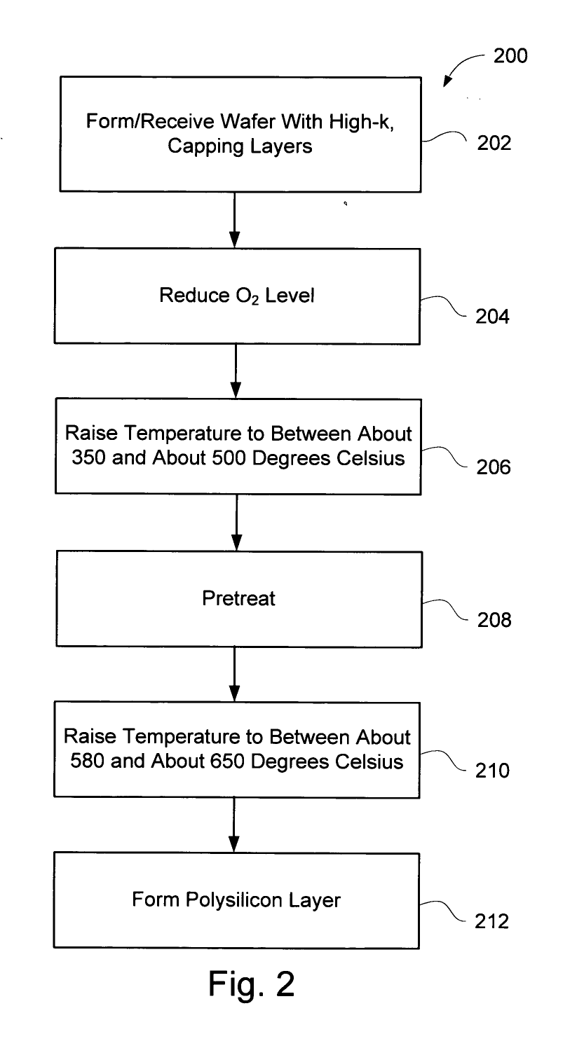

FIG. 2 is a flow chart 200 that shows how the smooth polysilicon layer 108 shown in FIG. 1 may be formed, according to one embodiment of the present invention. In an embodiment, the smooth polysilicon layer 108 may be formed by a chemical vapor deposition (“CVD”) process, such as a low pressure chemical vapor deposition (“LPCVD”) process, using a CVD chamber. While some embodiments may utilize CVD cold wall single wafer CVD equipment, many embodiments may utilize a hot wall batch reactor, which processes multiple wafers at a time. The term “chamber” as used herein, in the description as well as the claims, refers to a chamber of either one of these types of devices, as well as the chamber of other types of CVD equipment.

The wafer 100 with the substrate layer 102, high-k layer 104 and capping layer 106 may be received 202, or may be formed 202 using any suitable process.

In an embodiment, the oxygen level in the environment around the wafer 100 may be reduced 204. In some embodiments, the wafer 100 may be in a carrier before being inserted into a CVD chamber at this point. In some embodiments, the reduced oxygen level may be in a carrier as well as in a CVD chamber. In an embodiment, the oxygen level in the environment around the wafer 100 may be reduced 204 to below about 10 ppm. In another embodiment, a partial vacuum may created around the wafer to reduce 204 the oxygen level around the wafer 100 to a level of less than about 0.5 mTorr. In an embodiment, the reduced 204 oxygen level may be maintained for some or all of the process described by the flow chart 200. For example, in an embodiment, the reduced 204 oxygen level may be maintained during pretreatment 208 and/or polysilicon formation 212.

The temperature of the wafer 100 may be raised 206 to a temperature between about 350 degrees Celsius and about 500 degrees Celsius in an embodiment. In embodiments that employ a CVD chamber, the temperature of the CVD chamber may be raised 206 to such a temperature as well as the wafer 100. In an embodiment, the temperature of the wafer 100 and/or chamber may be raised 206 to a temperature of about 425 degrees Celsius, although other temperatures may be used.

The wafer 100 may then be pretreated 208. During this pretreatment 208, the wafer 100 and/or chamber may be held substantially at the temperature to which it was raised 206. In an embodiment, the pre-treating 208 may include flowing a silicon gas precursor in a CVD chamber. In an embodiment, this silicon gas precursor may comprise silane. In an embodiment, the pressure may be about 170 mTorr. In another embodiment, the pressure may be at least about 170 mTorr. In another embodiment, the pressure may be between about 170 mTorr and about 350 mTorr, although other pressures may be used. In an embodiment the flow rate of the silicon gas precursor may be about 0.7 slm for a chamber with a volume of about 180 liters. In an embodiment, this pretreatment 208 may be done for over five minutes. In an embodiment, the pretreatment 208 may be done for about fifteen minutes, although it may be performed for other time periods.

The temperature of the wafer 100 may be raised 210 after the pretreatment 208, in an embodiment. The temperature of the wafer 100 may be raised 210 to a temperature higher than that used during pretreatment 208 of the wafer 100 in an embodiment. The temperature of the wafer 100 may be raised 210 to a temperature between about 580 degrees Celsius and about 650 degrees Celsius in an embodiment. In embodiments that employ a CVD chamber, the temperature of the CVD chamber may be raised 210 to such a temperature, as well as the wafer 100. In an embodiment, the temperature of the wafer 100 and/or chamber may be raised 210 to a temperature of about 610 degrees Celsius, although other temperatures may be used.

The polysilicon layer 108 may be formed 212 on the wafer 100. During formation 212 of the polysilicon layer 108, the wafer 100 and/or chamber may be held substantially at the temperature to which it was raised 210. The formation 212 of the polysilicon layer 108 may be done by CVD or LPCVD in some embodiments. In an embodiment, the formation 212 of the polysilicon layer 108 may include flowing a silicon gas precursor in a CVD chamber. In an embodiment, this silicon gas precursor may comprise silane. In an embodiment, the pressure may be about 170 mtorr, although other pressures may be used. In an embodiment the flow rate of the silicon gas precursor may be about 0.7 slm for a chamber with a volume of about 180 liters. In an embodiment, this formation 212 may be done for a period of time sufficient to form 212 the polysilicon layer 108 with a desired thickness; thicker polysilicon layers 108 may require more time. In an embodiment with a polysilicon layer 108 having a thickness 110 of about 800 angstroms, the formation 212 may take about 11 minutes.

The formed 212 polysilicon layer 108 may have the smooth surface described above with respect to FIG. 1. This smoothness may be achieved by the formation process, without additional polishing or other smoothing steps. Further, the transition layer 103 (oxide layer or other material) may have a thickness that is substantially the same before the formation 212 of the polysilicon layer 108 as it is after the formation 212 of the polysilicon layer 108, in some embodiments. The transition layer 103 may have a thickness that is substantially the same before the process described in the flow chart 200 of FIG. 2 as it is after the process described in the flow chart 200 of FIG. 2, in some embodiments.

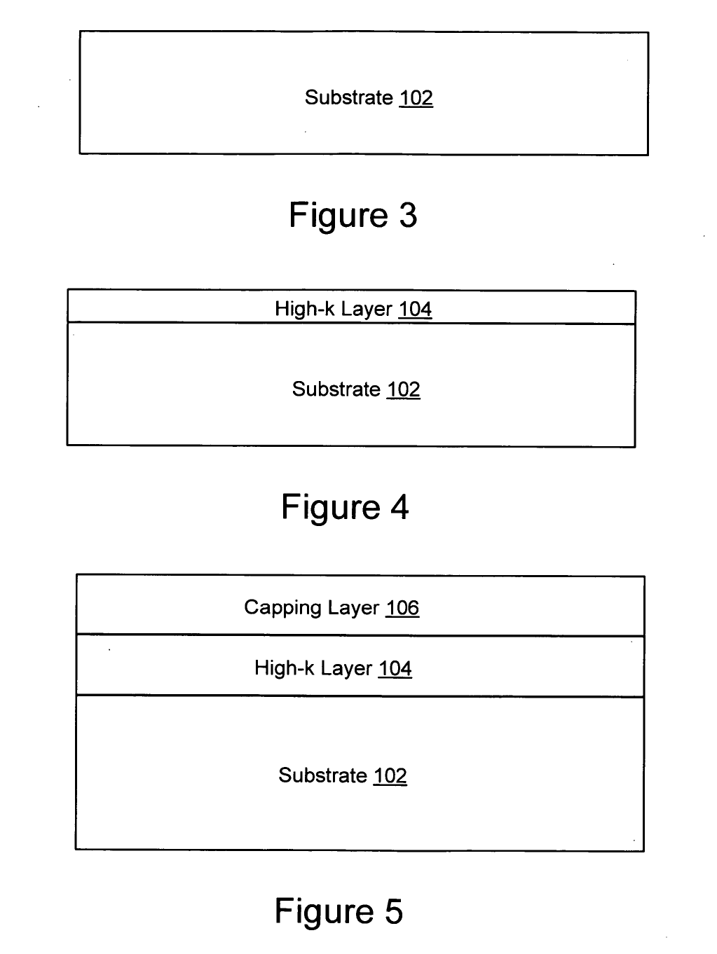

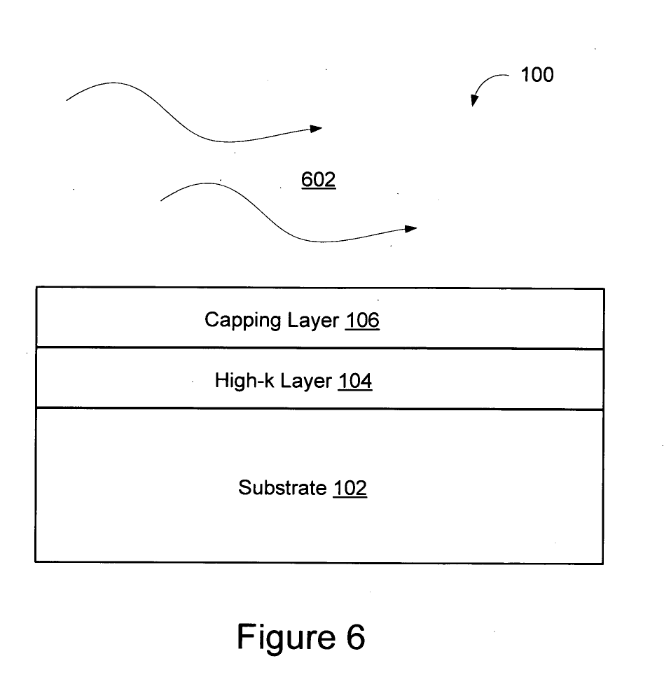

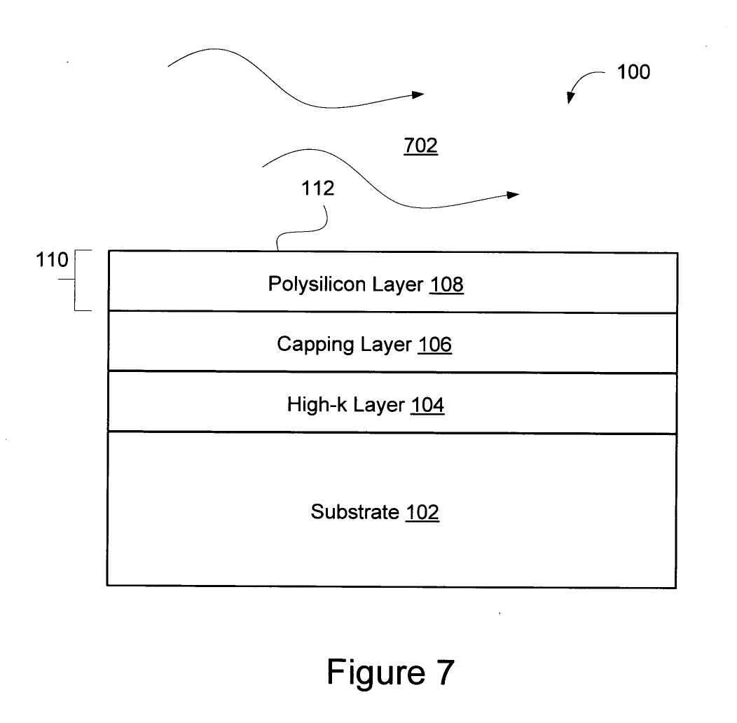

FIGS. 3 through 8 are cross sectional side views that illustrate the process described in the flow chart 200 of FIG. 2 in more detail. Note that transition layer 103, although it may be present, is not shown in these figures. FIGS. 3 through 5 illustrate how the wafer 100 with high-k and capping layers 104, 106 may be formed 202, according to one embodiment. FIGS. 6 and 7 illustrate other steps of the flow chart 200.

FIG. 3 is a cross sectional side view that illustrates the substrate 102. As stated above, the substrate 102 may comprise any material or materials that may serve as a foundation upon which a semiconductor device may be built. FIG. 4 is a cross sectional side view that illustrates the high-k layer 104 formed on the substrate 102. Any suitable process may be used to form the high-k layer 104. FIG. 5 is a cross sectional side view that illustrates the capping layer 106 formed on the high-k layer 104. Any suitable process may be used to form the capping layer 106.

FIG. 6 is a cross sectional side view that illustrates the pretreatment 208 of the wafer 100, according to one embodiment. In this embodiment, the wafer 100, including the substrate 102, high-k layer 104, and capping layer 106, has been brought to a temperature between about 350 and 500 degrees Celsius. The oxygen level has been reduced 204; there is very little oxygen in the environment around the wafer 100. The silicon precursor gas 602 is flowing in the chamber in which the wafer 100 is being pretreated 208.

FIG. 7 is a cross sectional side view that illustrates the formation 212 of the polysilicon layer 108, according to one embodiment. In this embodiment, the wafer 100, including the substrate 102, high-k layer 104, and capping layer 106, has been brought to a temperature between about 580 and 650 degrees Celsius. The oxygen level may remain reduced 204. The silicon precursor gas 702 is flowing, and the polysilicon layer 108 is being deposited to a desired thickness 110. In an embodiment, the wafer 100 may be as described and shown in FIG. 1 after this process.

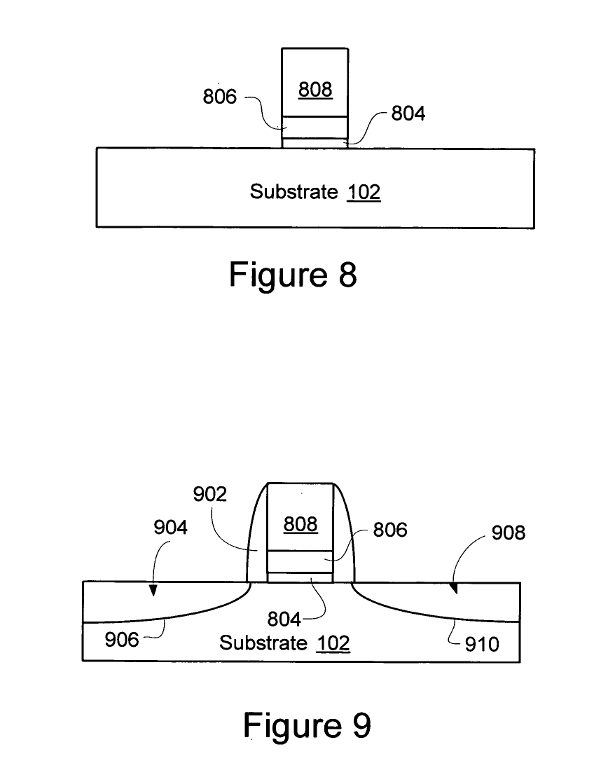

FIGS. 8 through 11 are cross sectional side views that illustrate how a device may be formed on the wafer 100 after formation 212 of the polysilicon layer 108, according to one embodiment of the present invention. In other embodiments, the wafer 100 with the polysilicon layer 108 may be used for other purposes and devices.

FIG. 8 is a cross sectional side view that illustrates the wafer 100 after portions of the high-k layer 104, capping layer 106, and polysilicon layer 108 have been removed, leaving behind a patterned high-k layer 804, patterned capping layer 806 and patterned polysilicon layer 808. Any suitable method may be used to pattern and remove portions of the high-k layer 104, capping layer 106, and polysilicon layer 108.

FIG. 9 is a cross-sectional side view that illustrates spacers 902 formed adjacent the sidewalls of the patterned high-k layer 804, patterned capping layer 806 and patterned polysilicon layer 808, and source and drain regions 904, 908 formed in the substrate 102, according to an embodiment. The source and drain regions 904, 908 may be formed by doping regions of the substrate 102 in an embodiment. In another embodiment, the source and drain regions 904, 908 may be formed be removing portions of the substrate 102 to form recesses 906, 910, then filling the recesses 906, 910 with a source/drain material. Such a material may extend beyond the top surface of the substrate 102, and may be doped during formation or after formation. Other suitable methods to make source and drain regions 904, 908 may also be used. Any suitable method may be used to make the spacers 902.

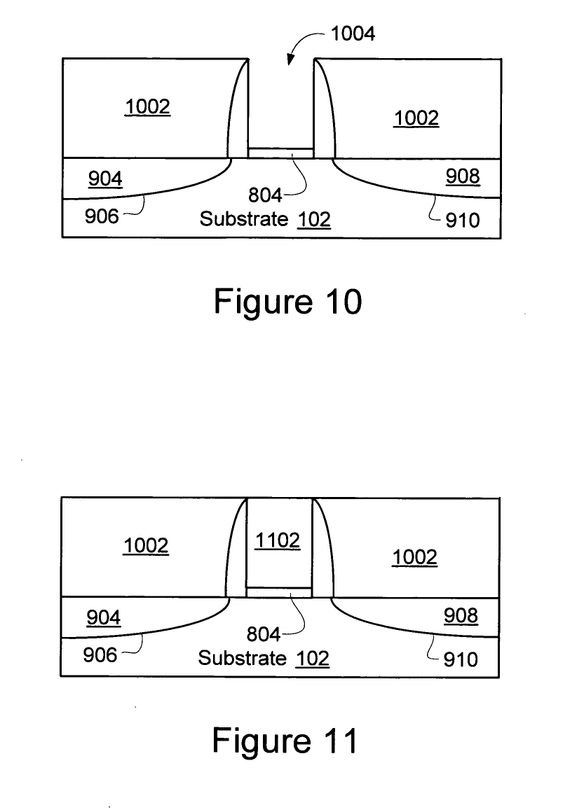

FIG. 10 is a cross-sectional side view that illustrates a first interlayer dielectric layer (ILD layer) 1002 and a trench 1004, according to one embodiment, according to an embodiment. Any suitable material may be used as the ILD layer 1002. The ILD layer 1002 may be formed by putting ILD material on the patterned high-k layer 804, patterned capping layer 806 and patterned polysilicon layer 808 as well as the source and drain regions 904, 908, then planarizing the ILD layer 1002, to remove the ILD layer 1002 material to expose the patterned polysilicon layer 808. The trench 1004 may then be formed by removing the patterned polysilicon layer 808. The patterned polysilicon layer 808 may be removed by any suitable method. In some embodiments, the capping layer 806 may also be removed, as is illustrated in FIG. 10. In yet other embodiments, the high-k layer 804 may also be removed in addition to the capping layer 806. In some embodiments, both the capping layer 806 and high-k layer 804 may remain in place.

FIG. 11 is a cross-sectional side view that illustrates a metal gate electrode 1102 formed in the trench 1004, according to one embodiment. The metal gate electrode 1102 may comprise a metal gate electrode layer and may also comprise additional layers and materials. Thus, the metal gate electrode 1102 may be a single- or multi-layer structure. Any suitable method may be used to form the metal gate electrode 1102.

The metal gate electrode 1102 may include a metal work function layer. The metal work function layer may be an n-type, p-type, or mid-gap metal gate electrode layer in various embodiments. Materials that may be used to form n-type metal gate electrode layers include: hafnium, zirconium, titanium, tantalum, aluminum, their alloys (e.g., metal carbides that include these elements, i.e., hafnium carbide, zirconium carbide, titanium carbide, tantalum carbide, and aluminum carbide), and aluminides (e.g., an aluminide that comprises hafnium, zirconium, titanium, tantalum, or tungsten). Materials for forming p-type metal gate electrode layers include: ruthenium, palladium, platinum, cobalt, nickel, and conductive metal oxides, e.g., ruthenium oxide. Materials for forming mid-gap metal gate electrode layers include: stoichiometric titanium nitride, tantalum nitride, or another mid-gap material.

Additional process steps may be performed to complete the device, as will be appreciated by those of skill in the art.

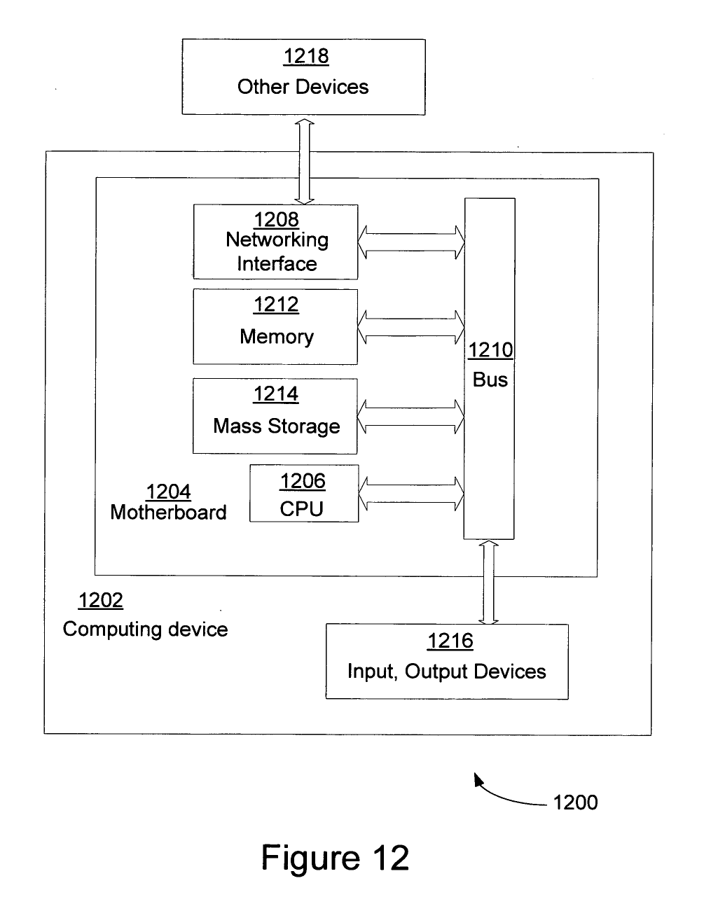

FIG. 12 illustrates a system 1200 in accordance with one embodiment of the present invention. One or more devices formed from the wafer 100 with a smooth polysilicon layer 108 may be included in the system 1200 of FIG. 12. As illustrated, for the embodiment, system 1200 includes a computing device 1202 for processing data. Computing device 1202 may include a motherboard 1204. Coupled to or part of the motherboard 1204 may be in particular a processor 1206, and a networking interface 1208 coupled to a bus 1210. A chipset may form part or all of the bus 1210.

Depending on the applications, system 1200 may include other components, including but are not limited to volatile and non-volatile memory 1212, a graphics processor (integrated with the motherboard 1204 or connected to the motherboard as a separate removable component such as an AGP or PCI-E graphics processor), a digital signal processor, a crypto processor, mass storage 1214 (such as hard disk, compact disk (CD), digital versatile disk (DVD) and so forth), input and/or output devices 1216, and so forth.

In various embodiments, system 1200 may be a personal digital assistant (PDA), a mobile phone, a tablet computing device, a laptop computing device, a desktop computing device, a set-top box, an entertainment control unit, a digital camera, a digital video recorder, a CD player, a DVD player, or other digital device of the like.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A method for making a semiconductor device, comprising:
pretreating a wafer having a substrate layer, a high-k dielectric layer on the substrate layer, and a capping layer on the high-k dielectric layer with a silicon gas precursor at a first temperature; and
forming, after pretreating the wafer, a polysilicon layer on the high-k layer at a second temperature higher than the first temperature.

2. The method of claim 1, further comprising reducing the level of oxygen in an atmosphere around the wafer to about 10 ppm or below during pretreatment of the wafer.

3. The method of claim 1, wherein the first temperature is between about 350 to 500 degrees Celsius, and the wafer is pretreated with the silicon gas precursor for at least about five minutes.

4. The method of claim 3, wherein the wafer is pretreated at a pressure of at least about 170 mTorr.

5. The method of claim 3, wherein the silicon gas precursor is a silane gas.

6. The method of claim 3, wherein the second temperature is between about 580 and 650 degrees Celsius, and forming the polysilicon layer comprises depositing the polysilicon layer with a low pressure chemical vapor deposition process with a flow of a silicon gas precursor.

7. The method of claim 6, wherein the silicon gas precursor is a silane gas.

8. The method of claim 6, wherein the wafer is pretreated in a same low pressure chemical vapor deposition chamber and the polysilicon layer is formed in the same chamber.

9. The method of claim 1, wherein the formed polysilicon layer has a top surface with a roughness of less than about 6 nanometers RMS after formation without use of additional smoothing processes.

10. The method of claim 1, wherein the formed polysilicon layer has a top surface with a roughness of less than about 3 nanometers RMS after formation without use of additional smoothing processes.

11. The method of claim 1, wherein the wafer further comprises an oxide layer between the high-k dielectric layer and the substrate and having a thickness, and wherein the thickness of the oxide layer is substantially the same after formation of the polysilicon layer as it is before the wafer is pretreated.

12. A method for making a semiconductor device, comprising:
pretreating a wafer having a substrate layer, a high-k dielectric layer on the substrate layer, and a capping layer on the high-k dielectric layer by flowing a first silicon gas precursor in a low pressure chemical vapor deposition chamber containing the wafer at a temperature between about 350 degrees Celsius and about 500 degrees Celsius; and
forming, after pretreating the wafer, a polysilicon layer on the high-k dielectric layer by flowing a second silicon gas precursor in the low pressure chemical vapor deposition chamber at a temperature between about 580 degrees Celsius and about 650 degrees Celsius.

13. The method of claim 12, further comprising reducing the level of oxygen in an atmosphere around the wafer to about 10 ppm or below during pretreatment of the wafer and formation of the polysilicon layer.

14. The method of claim 12, further comprising reducing the level of oxygen in an atmosphere around the wafer to about 0.5 mTorr or less during pretreatment of the wafer and formation of the polysilicon layer.

15. The method of claim 12, wherein the first and second silicon gas precursors are substantially the same precursors.

16. The method of claim 12, wherein the wafer is pretreated for at least about five minutes.

17. The method of claim 16, wherein the formed polysilicon layer has a top surface with a roughness of less than about 6 nanometers RMS.

18. The method of claim 17, further comprising:
patterning the high-k dielectric layer, capping layer, and polysilicon layer;
forming spacers adjacent the patterned polysilicon layer;
forming source and drain regions in the substrate;
removing the patterned polysilicon layer, to leave behind a trench between the spacers; and
forming a replacement gate electrode in the trench.
